(19) United States
(12) Patent Application Publication
(10) Pub. No.: US 2019/0301028 A1
(43) Pub. Date: Oct. 3, 2019

(54) COMPOSITION FOR SURFACE TREATMENT, AND METHOD FOR SURFACE TREATMENT AND METHOD FOR PRODUCING SEMICONDUCTOR SUBSTRATE USING THE SAME

(71) Applicant: FUJIMI INCORPORATED, Kiyosu-shi, Aichi (JP)

(72) Inventor: Jingzhi CHEN, Tongluo Township (TW)

(73) Assignee: FUJIMI INCORPORATED, Kiyosu-shi, Aichi (JP)

(21) Appl. No.: 16/335,629

(22) PCT Filed: Aug. 28, 2017
(86) PCT No.: PCT/JP2017/030789

§ 371 Date: Mar. 21, 2019

(30) Foreign Application Priority Data
Sep. 23, 2016 (JP) 2016-185775

(51) Int. Cl. C23G 1/10; H01L 21/304; C09G 1/02

(52) U.S. Cl. CPC C23G 1/10; C09G 1/02; H01L 21/304

(57) ABSTRACT

To provide a means for suppressing the rate of dissolution of tungsten while sufficiently removing the impurities remaining on a surface of a polished object to be polished having a layer containing at least tungsten, and tetraethyl orthosilicate or silicon nitride. To provide a composition for surface treatment, which contains a polymer compound having a sulfonic acid (salt) group, at least one compound selected from an amino acid and a polyol, and a dispersing medium, and is used for treating a surface of a polished object to be polished having a layer containing at least tungsten, and tetraethyl orthosilicate or silicon nitride.

### TECHNICAL FIELD

The present invention relates to a composition for surface treatment, and to a method for surface treatment and a method for producing a semiconductor substrate, using the composition for surface treatment.

### BACKGROUND ART

In recent years, with the multi-layered wiring on a surface of a semiconductor substrate, when a device is produced, a so-called chemical mechanical polishing (CMP) technique for physically polishing and planarizing a semiconductor substrate is used. CMP is a method for planarizing a surface of an object to be polished (polished object) of a semiconductor substrate or the like by using a polishing composition (slurry) containing abrasive grains of silica, alumina, ceria or the like, an anticorrosive, a surfactant, and the like, and the object to be polished (polished object) is a wiring, a plug, or the like, which is made of silicon, polysilicon, tetraethyl orthosilicate, silicon nitride, a metal, or the like.

On a surface of a semiconductor substrate after a CMP step, a large amount of impurities (defects) remain. In the impurities, for example, abrasive grains derived from a polishing composition that has been used in CMP, a metal, an anticorrosive, an organic matter of a surfactant or the like, a silicon-containing material that is an object to be polished, a silicon-containing material or a metal, which has been generated by polishing a metal wiring, a plug or the like, and further an organic matter of pad scraps or the like generated from various kinds of pads or the like, are included.

When a surface of a semiconductor substrate is contaminated with these impurities, the electric characteristics of the semiconductor are adversely affected, and the reliability of a device may be lowered. Therefore, it is desirable to introduce a cleaning step after a CMP step to remove these impurities from the surface of the semiconductor substrate.

As such a cleaning composition, for example, in Patent Literature 1, it has been disclosed that by using a cleaning composition for a semiconductor substrate, which contains polycarboxylic acid or hydroxycarboxylic acid, a sulfonic acid type anionic surfactant, a carboxylic acid type anionic surfactant, and water, impurities can be removed without corroding the surface of a substrate.

### CITATION LIST

### Patent Literatures

Patent Literature 1: JP 2012-74678 A

### SUMMARY OF INVENTION

### Technical Problem

However, in recent years, in cleaning a polished object to be polished having tetraethyl orthosilicate (TEOS) or silicon nitride (SiN), further improvement is required for the removal of impurities (defects). In addition, in a case where tungsten is contained in a polished object to be polished, there is a tendency that the tungsten dissolves in a cleaning composition and a surface of the polished object to be polished becomes roughened, and improvement is also required for this tendency.

Accordingly, the present invention has been made in view of the above-described problems, and an object of the present invention to provide a composition for surface treatment for improving the surface roughness of a polished object to be polished by sufficiently removing the impurities remaining on a surface of the polished object to be polished having a layer containing at least tungsten, and tetraethyl orthosilicate or silicon nitride, and further by reducing the rate of dissolution of tungsten.

### Solution to Problem

In view of the above-described problem, the present inventors made intensive studies. As a result, the present inventors found that by containing a polymer compound having a sulfonic acid (salt) group, at least one compound selected from an amino acid and a polyol, and a dispersing medium in a composition for surface treatment, the effect of removing impurities on a surface of a polished object to be polished is remarkably improved, and further by reducing the rate of dissolution of the tungsten contained in the polished object to be polished, the surface roughness of the polished object to be polished is improved, and thus have completed the present invention.

That is, the above-described problems of the present invention is solved by the following means.

A composition for surface treatment, containing a polymer compound having a sulfonic acid (salt) group, at least one compound selected from an amino acid and a polyol, and a dispersing medium in a composition for surface treatment contains, and being used for a polished object to be polished having a layer containing at least tungsten, and tetraethyl orthosilicate or silicon nitride.

### Advantageous Effects of Invention

According to the present invention, there is provided a means by which the impurities remaining on a surface of a polished object to be polished having a layer containing at least tungsten, and TEOS or silicon nitride are sufficiently removed, further the rate of dissolution of the tungsten contained in the polished object to be polished is reduced, and the surface roughness of the polished object to be polished can be improved.

### DESCRIPTION OF EMBODIMENTS

According to one embodiment of the present invention, there is provided a composition for surface treatment, containing a polymer compound having a sulfonic acid (salt) group, at least one compound selected from an amino acid and a polyol, and a dispersing medium, and being used for a polished object to be polished having a layer containing at least tungsten, and tetraethyl orthosilicate or silicon nitride.

From the viewpoint of removing the impurities (foreign matters such as particles, metal contamination, organic residues, and pad scraps) remaining on a surface of a polished object to be polished (substrate) after a CMP step, the composition for surface treatment according to the present invention changes the surface state of the surface of the polished object to be polished (substrate). Further, also from the viewpoint of improving the roughness of a surface of a polished object to be polished (substrate), by suppressing the dissolution of tungsten, the composition for surface treatment according to the present invention changes the surface state of the polished object to be polished (substrate). Accordingly, a composition used in the present invention is referred to as a composition for surface treatment. Further, a step of changing the surface state of the substrate is referred to as a surface treatment step.

Hereinafter, the present invention will be described. However, the present invention is not limited only to the following embodiments.

[Polished Object to be Polished]

In the present specification, the expression “polished object to be polished” means an object to be polished after being polished in a polishing step. As the polishing step, it is not particularly limited, and a CMP step is preferred.

The polished object to be polished according to the present invention is a polished object to be polished having a layer containing at least tungsten, and TEOS or silicon nitride (hereinafter, also referred to as “object to be subjected to surface treatment”).

The polished object to be polished is preferably a polished semiconductor substrate, and more preferably a semiconductor substrate after CMP. The reason for this is that since in particular, impurities may cause breakdown of a semiconductor device, in a case where the polished object to be polished is a polished semiconductor substrate, a step of removing the impurities as much as possible is required as the cleaning step of a semiconductor substrate.

As the polished object to be polished having a layer containing at least tungsten, and TEOS or silicon nitride, it is not particularly limited, and for example, a polished object to be polished or the like including a layer containing tungsten, and silicon nitride or TEOS can be mentioned. Specific examples of the polished object to be polished include a polished semiconductor substrate having a structure in which tungsten is formed on a silicon nitride film or a TEOS film, and a polished semiconductor substrate or the like having a structure in which a tungsten part, a silicon nitride film, and a TEOS film are all exposed.

[Composition for Surface Treatment]

One embodiment of the present invention is a composition for surface treatment, containing a polymer compound having a sulfonic acid (salt) group, at least one compound selected from an amino acid and a polyol, and a dispersing medium, and being used for a polished object to be polished having a layer containing at least tungsten, and TEOS or silicon nitride.

The composition for surface treatment according to one embodiment of the present invention can be used as a composition for surface treatment for selectively removing impurities and further for reducing the rate of dissolution of tungsten to improve the surface roughness, in a surface treatment step.

The present inventors presume the mechanism by which the above-described problems are solved by the present invention as follows.

At first, the action mechanism by which impurities are removed from an object to be subjected to surface treatment will be described. In the polymer compound having a sulfonic acid (salt) group according to the present invention, a micelle can be formed due to the affinity between the part other than the sulfonic acid (salt) group of the polymer compound (that is, a polymer chain moiety of the polymer compound) and the impurities (particularly, a hydrophobic moiety). Accordingly, it is considered that this micelle is dissolved or dispersed in a composition for surface treatment, and impurities being hydrophobic components are effectively removed.

Further, a part of an anionized sulfonic acid group of a sulfonic acid group-containing polymer acts on surfaces of a positively charged object to be subjected to surface treatment and impurities, and electrostatically adsorbs to the object to be subjected to surface treatment and impurities. As a result, the anionized sulfonic acid group of a polymer compound adsorbed onto a surface of the impurity and the anionized sulfonic acid group of a polymer compound adsorbed onto a surface of the object to be subjected to surface treatment are electrostatically repulsed. It is considered that by utilizing such electrostatic repulsion, impurities can be effectively removed.

Further, the sulfonic acid group-containing polymer adsorbed onto a surface of an object to be subjected to surface treatment is easily removed after a cleaning step.

Next, the action mechanism of suppressing the rate of dissolution of tungsten will be presumed. The present inventors have found that with the cleaning by using a cleaning liquid disclosed, for example, in Patent Literature 1, the tungsten contained in a polished object to be polished is dissolved, or the surface of a polished object to be polished becomes roughened. It is considered that such dissolution of a tungsten layer and such increase in surface roughness are attributed to the fact that the tungsten layer formed on a surface of a polished object to be polished forms a hydrate (WₓO_{y}^{A-}) with the water contained in a cleaning liquid (composition used for cleaning) and becomes easy to dissolve. In this regard, in one embodiment of the present invention, with the composition for surface treatment having a positively charged amino acid structure, the amino acid structure is electrostatically adsorbed onto a surface of a tungsten layer, a protective film is formed on the surface of the tungsten layer, and the dissolution of the tungsten can be suppressed. On the other hand, there is a part in which the surface of tungsten is partially oxidized to form tungsten oxide. In this regard, in one embodiment of the present invention, since the composition for surface treatment has a polyol having a large number of hydroxyl groups, the hydroxyl group of the polyol and tungsten oxide act due to the hydrogen bonding, a protective film is formed on a surface of the tungsten oxide, and the dissolution of the tungsten can be suppressed. Therefore, the surface roughness of a polished object to be polished due to the excessive dissolution of tungsten can also be improved.

In this regard, the above-described mechanism is based on speculation, and the correct or incorrect does not affect the technical scope of the present invention.

Hereinafter, each of the components contained in the composition for surface treatment will be described.

<Polymer Compound Having Sulfonic Acid (Salt) Group>

The composition for surface treatment according to one embodiment of the present invention essentially contains a polymer compound having a sulfonic acid (salt) group. The polymer compound having a sulfonic acid (salt) group (also referred to as “sulfonic acid group-containing polymer”) contributes to the removal of impurities by the composition for surface treatment. In this regard, in the present specification, the expression “sulfonic acid (salt) group” is referred to as “sulfonic acid group” or “sulfonic acid salt group”.

The sulfonic acid group-containing polymer is not particularly limited as long as it has a sulfonic acid (salt) group, and a known compound can be used. Examples of the sulfonic acid group-containing polymer include a polymer compound or the like obtained by sulfonating a polymer compound to be a base, and a polymer compound obtained by (co)polymerizing a monomer having a sulfonic acid (salt) group.

The number of sulfonic acid groups of the sulfonic acid group-containing polymer according to the present invention is not particularly limited as long as it is 1 or more, and in view of the balance between the suppression of the dissolution or the like of a tungsten layer and the ease of the removal of a sulfonic acid group-containing polymer after surface treatment, the number of sulfonic acid groups is preferably 1 or more and 1,000 or less, more preferably 100 or more and 800 or less, and particularly preferably 300 or more and 500 or less. Further, the sulfonic acid group of a sulfonic acid group-containing polymer may be introduced to the end of the polymer, or may be introduced as a side chain of the main chain of the polymer. The sulfonic acid group of a sulfonic acid group-containing polymer may be directly bonded to the main chain when introduced as a side chain of the main chain of the polymer, or may be bonded to the main chain while having another substituent between the sulfonic acid group and the main chain. As the substituent between the sulfonic acid group and the main chain of a sulfonic acid group-containing polymer, for example, an alkylene group having 1 to 24 carbon atoms, an arylene group having 6 to 24 carbon atoms, or the like can be mentioned. From the viewpoint of the effect of suppressing the dissolution of tungsten or the increase in surface roughness, as the substituent, an arylene group having 6 to 24 carbon atoms is preferred.

More specific examples of the sulfonic acid group-containing polymer according to the present invention include a sulfonic acid group-containing modified polyvinyl alcohol, a sulfonic acid group-containing modified polystyrene such as polystyrene sulfonic acid or a salt thereof, a sulfonic acid group-containing modified polyvinyl acetate, a sulfonic acid group-containing modified polyester, and a copolymer of (meth)acrylic group-containing monomer-sulfonic acid group-containing monomer such as a copolymer of (meth)acrylic acid-sulfonic acid group-containing monomer. In this regard, the term “(meth)acrylic” means “acrylic or methacrylic”. At least apart of the sulfonic acid groups possessed by these polymers may be in a form of a salt. Examples of the salt include an alkali metal salt such as a sodium salt, and a potassium salt, a salt of Group 2 element such as a calcium salt, and a magnesium salt, an amine salt, and an ammonium salt.

In addition, in a case where the sulfonic acid-based polymer is a sulfonic acid group-containing modified polyvinyl alcohol, from the viewpoint of the solubility, the saponification degree is preferably 80% or more, and more preferably 85% or more (upper limit 100%).

In the present invention, the weight average molecular weight of a sulfonic acid group-containing polymer is preferably 1,000 or more. When the weight average molecular weight is 1,000 or more, the effect of removing impurities is further enhanced. The reason for this is presumed that the coatability when a composition for surface treatment or impurities are covered becomes more favorable, and action of removing impurities from a surface of the composition for surface treatment, or action of preventing impurities from re-adhering onto the surface of the composition for surface treatment is further improved. From the similar point of view, the weight average molecular weight is more preferably 2,000 or more, and furthermore preferably 8,000 or more.

Further, the weight average molecular weight of a sulfonic acid group-containing polymer is preferably 100,000 or less. When the weight average molecular weight is 100,000 or less, the effect of removing impurities is further enhanced. The reason for this is presumed that the removability of the sulfonic acid group-containing polymer after a cleaning step becomes more favorable. From the similar point of view, the weight average molecular weight is more preferably 90,000 or less, and furthermore preferably 80,000 or less.

The weight average molecular weight can be measured by gel permeation chromatography (GPC) using a polystyrene of which the molecular weight is known as the reference substance.

As the sulfonic acid-based polymer, a commercially available product may be used, and for example, GOHSENX (registered trademark) L-3226 or GOHSENX (registered trademark) CKS-50 manufactured by The Nippon Synthetic Chemical Industry Co., Ltd.; ARON (registered trademark) A-6012, A-6016A, or A-6020 manufactured by TOAGOSEI CO., LTD.; Poly-NaSS (registered trademark) PS-1 manufactured by Tosoh Organic Chemical Co., Ltd.; 42653 polystyrene sulfonic acid manufactured by Alfa Aesar; or the like can be used.

The content of the sulfonic acid group-containing polymer is preferably 0.01% by mass or more relative to the total mass of the composition for surface treatment. When the content of the sulfonic acid group-containing polymer is 0.01% by mass or more, the effect of removing impurities is further improved. The reason for this is presumed that when a composition for surface treatment and impurities are coated with the sulfonic acid group-containing polymer, the coating is made in a larger area. Further, it is presumed that with the increase in the number of sulfonic acid (salt) groups, the electrostatic adsorption or the repulsion effect can be more strongly exhibited. From the similar point of view, the content of the sulfonic acid group-containing polymer is preferably 0.05% by mass or more, and more preferably 0.09% by mass or more, relative to the total mass of the composition for surface treatment.

In addition, the content of the sulfonic acid group-containing polymer is preferably 10% by mass or less relative to the total mass of the composition for surface treatment. When the content of the sulfonic acid group-containing polymer is 10% by mass or less, the effect of removing impurities is further enhanced. The reason for this is presumed that the removability of the sulfonic acid group-containing polymer after a cleaning step becomes more favorable. From the similar point of view, the content of the sulfonic acid group-containing polymer is preferably 5% by mass or less, and more preferably 1% by mass or less, relative to the total mass of the composition for surface treatment.

<Amino Acid and Polyol>

The composition for surface treatment according to one embodiment of the present invention essentially contains at least one compound selected from an amino acid and a polyol. In the present invention, the amino acid and the polyol are added as inhibitors of the rate of dissolution of tungsten. By containing at least one kind of an amino acid and a polyol, the composition for surface treatment according to the present invention reduces the rate of dissolution of the tungsten contained in a polished object to be polished, and the surface roughness of the polished object to be polished can be improved.

[Amino Acid]

The amino acid used in the composition for surface treatment according to the present invention refers to an organic compound having both of the functional groups of an amino group and a carboxyl group. Ina preferred embodiment of the present invention, the PI value (isoelectric point) of amino acid is preferably 7.0 or more, more preferably 8.0 or more, and particularly preferably 10.0 or more. The reason for this is presumed that the composition for surface treatment according to one embodiment of the present invention is acidic, under such an acidic environment, an amino acid having a PI value of 7.0 or more as described above is positively charged and is easy to electrostatically adsorb onto a negatively charged surface of tungsten, and the rate of dissolution of the tungsten can be decreased. As the amino acid having a PI value of 7.0 or more, arginine, lysine, histidine, or the like can be mentioned, but it is not limited thereto.

In another preferred embodiment of the present invention, from the viewpoint similar to the above, the amino acid used in the composition for surface treatment is preferably a basic amino acid. As the basic amino acid, arginine, lysine, histidine, or the like can be mentioned, but it is not limited thereto.

In another preferred embodiment of the present invention, from the viewpoint of the interaction with a surface of tungsten, the amino acid used in the composition for surface treatment preferably contains a sulfur atom. As the sulfur atom-containing amino acid, methionine, cysteine, homocysteine, or the like can be mentioned, but it is not limited thereto.

[Polyol]

The polyol used in the composition for surface treatment according to the present invention is not particularly limited as long as it is a compound having 2 or more alcoholic hydroxyl groups in the molecule. From the viewpoint of the formation of a hydrogen bond, the polyol is preferably at least one kind selected from a polyhydric alcohol and a saccharide. Further, in a case of using a compound with a low molecular weight as the polyol, a compound having 2 to 10 alcoholic hydroxyl groups is preferred. Ina case of using a polymer compound as the polyol, the number of alcoholic hydroxyl groups is not limited as described above, but a polymer compound having a weight average molecular weight of 90 to 3000 is preferred. Specific examples of the polyhydric alcohol include glycol, glycerin, polyglycerin, and the like. Specific examples of the saccharide include lactitol, maltitol, mannitol, and the like.

The amino acid and the polyol may be used singly alone, or may be used in combination of two or more kinds thereof at an arbitrary ratio.

The content of the amino acid and the polyol is preferably 0.01% by mass or more relative to the total mass of the composition for surface treatment. When the content of the amino acid and the polyol is 0.01% by mass or more, the effect of suppressing the rate of dissolution of tungsten is further improved. The reason for this is presumed that when a composition for surface treatment is coated with the amino acid and the polyol, the coating is made in a larger area. From the similar point of view, the content of the amino acid and the polyol is preferably 0.03% by mass or more, and more preferably 0.05% by mass or more, relative to the total mass of the composition for surface treatment.

Further, the content of the amino acid and the polyol is preferably 10% by mass or less relative to the total mass of the composition for surface treatment. When the content of the amino acid and the polyol is 10% by mass or less, the effect of removing impurities is further enhanced. The reason for this is presumed that the removability of the amino acid and the polyol after a cleaning step becomes more favorable. From the similar point of view, the content of the amino acid and the polyol is more preferably 5% by mass or less, and furthermore preferably 1% by mass or less, relative to the total mass of the composition for surface treatment.

In this regard, the above-described content refers to a content of one kind of amino acid and polyol in a case of using one kind of the amino acid and the polyol. Further, the above-described content means the total content of two or more kinds of amino acid and polyol in a case of using the amino acid and the polyol in combination of two or more kinds thereof.

<pH Adjusting Agent>

The composition for surface treatment according to one embodiment of the present invention preferably contains an acid as a pH adjusting agent. In this regard, in the present specification, a sulfonic acid-based polymer is handled as being different from the acid as the additive agent described here. It is presumed that the acid plays a role of charging the surface of the composition for surface treatment containing silicon nitride or TEOS and the surfaces of the impurities with positive charges, and it is considered that the acid contributes to the removal of impurities by the composition for surface treatment.

As the acid, either an inorganic acid or an organic acid may be used. As the inorganic acid, it is not particularly limited, and examples of the inorganic acid include sulfuric acid, nitric acid, boric acid, carbonic acid, hypophosphorous acid, phosphorous acid, phosphoric acid, and the like. As the organic acid, it is not particularly limited, and examples of the organic acid include a carboxylic acid such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid; methanesulfonic acid; ethanesulfonic acid; and isethionic acid.

Among them, from the viewpoint that the effect of charging a surface of a composition for surface treatment and surfaces of impurities with positive charges becomes more favorable, the acid is more preferably maleic acid or nitric acid, and furthermore preferably nitric acid.

In this regard, the acid may be used alone or in combination of two or more kinds thereof.

The content of the acid is preferably 0.05% by mass or more relative to the total mass of the composition for surface treatment. When the content of the acid is 0.05% by mass or more, the effect of removing impurities is further improved. The reason for this is presumed that the effect of charging a surface of a composition for surface treatment containing silicon nitride or TEOS and surfaces of impurities with positive charges becomes favorable. From the similar point of view, the content of the acid is preferably 0.1% by mass or more, and more preferably 0.15% by mass or more, relative to the total mass of the composition for surface treatment. Further, the content of the acid is preferably 10% by mass or less relative to the total mass of the composition for surface treatment. When the content of the acid is 10% by mass or less, the damage to a device, which is caused due to a low pH, can be reduced. From the similar point of view, the content of the acid is more preferably 5% by mass or less, and furthermore preferably 3% by mass or less, relative to the total mass of the composition for surface treatment.

The pH value of the composition for surface treatment according to one embodiment of the present invention is preferably acidic. In a case where the pH value is 7 or less, an effect of charging a surface of the composition for surface treatment or surfaces of impurities with positive charges is obtained, and an effect of sufficiently removing impurities can be obtained. Accordingly, in one embodiment of the present invention, the pH value of the composition for surface treatment is preferably 7 or less, more preferably 4 or less, and furthermore preferably 3 or less. Further, the pH value is preferably 1 or more. When the pH value is 1 or more, the damage to a device, which is caused due to a low pH, can be reduced.

In this regard, the pH value of the composition for surface treatment can be confirmed by a pH meter (model number: LAQUA, manufactured by HORIBA Ltd.).

In a case where the pH value is adjusted, a component other than the preferred components of the composition for surface treatment according to one embodiment of the present invention is not desirably added as much as possible because the component may cause impurities. From this reason, the composition for surface treatment is preferably adjusted to only with an acid and a sulfonic acid group-containing polymer. However, in a case where it is difficult to obtain a desired pH value only with these acid and sulfonic acid group-containing polymer, other additive agents such as an alkali that can be arbitrarily added may be used for adjusting the pH within the range not inhibiting the effects of the present invention.

<Dispersing Medium>

The composition for surface treatment according to one embodiment of the present invention essentially contains a dispersing medium (solvent). The dispersing medium has a function of dispersing or dissolving respective components. The dispersing medium is more preferably only water. Further, the dispersing medium may also be a mixed solvent of water and an organic solvent in order to disperse or dissolve respective components. In this case, examples of the organic solvent to be used include acetone, acetonitrile, ethanol, methanol, isopropanol, glycerin, ethylene glycol, and propylene glycol, which are each an organic solvent miscible with water. In addition, these organic solvents may be used to disperse or dissolve respective components without being mixed with water, and then the dispersed or dissolved mixture may be mixed with water. These organic solvent may be used alone or in combination of two or more kinds thereof.

From the viewpoint of inhibiting the contamination of an object to be cleaned and the action of other components, the water is preferably a water not containing impurities as much as possible. For example, a water in which the total content of the transition metal ions is 100 ppb or less is preferred. In this regard, the purity of water can be increased, for example, with an operation of removing impurity ions by using an ion exchange resin, of removing foreign matters by a filter, or of distillation or the like. Specifically, as the water, for example, deionized water (ion exchanged water), pure water, ultrapure water, distilled water, or the like is preferably used.

<Other Additive Agents>

The composition for surface treatment according to one embodiment of the present invention may contain other additive agents at an arbitrary ratio as needed within the range not inhibiting the effects of the present invention. However, a component other than the essential components of the composition for surface treatment according to one embodiment of the present invention is not desirably added as much as possible because the component may cause impurities, and therefore, the addition amount is preferably as small as possible, and more preferably the additive agents are not contained. Examples of other additive agents include an alkali, an antiseptic agent, a dissolved gas, a reducing agent, an oxidizing agent, alkanol amines, and the like.

<Method for Surface Treatment>

In the specification of the present application, the method for surface treatment and the surface treatment step refer to a method and a step, respectively of reducing impurities on a surface of a polished object to be polished without using polishing granules.

One embodiment of the present invention is a method for surface treatment, in which by using the composition for surface treatment according to one embodiment of the present invention, a polished object to be polished is treated to reduce impurities on a surface of the polished object to be polished. In particular, it is preferred to use a method for surface treatment, in which by using the composition for surface treatment according to one embodiment of the present invention, a surface of a polished object to be polished having a layer containing at least tungsten, and tetraethyl orthosilicate or silicon nitride is treated.

As a general step, the method for surface treatment may include a step such as a step in which an object to be subjected to surface treatment is immersed in the composition for surface treatment according to the present invention and subjected to ultrasonic treatment, a step in which a brush is brought into contact with one surface or both surfaces of an object to be subjected to surface treatment, and the surface of the object to be subjected to surface treatment is rubbed with the brush while supplying a composition for surface treatment to the contact part, in a state that the object to be subjected to surface treatment is held, or a step in which a composition for surface treatment is flowed to an object to be subjected to surface treatment while rotating and treating the object to be subjected to surface treatment by using a polishing pad. In these steps, the impurities on a surface of an object to be polished are removed by the mechanical force generated by ultrasonic waves or by the frictional force with a brush or a polishing pad and by the chemical action with a composition for surface treatment.

As the surface treatment device, a common polishing device to which a holder for holding an object to be subjected to surface treatment, a motor capable of changing the rotation speed, and the like are attached, and which has a polishing table, may be used. As the polishing device, either a one-side polishing device or a double-side polishing device may be used. Specifically, as the polishing device, for example, Mirra Mesa manufactured by Applied Materials, Inc., FREX 300E manufactured by Ebara Corporation, or the like can be preferably used. In this regard, it is more efficient and preferable to use a device similar to the polishing device used in a CMP step.

The surface treatment conditions are not also particularly limited, and can be appropriately set depending on the kind of an object to be subjected to surface treatment, and the kind and amount of impurities to be removed. For example, the rotation speed of the object to be subjected to surface treatment is preferably 10 rpm or more and 100 rpm or less, the pressure (polishing pressure) applied to the object to be subjected to surface treatment is preferably 0.5 psi or more and 10 psi or less, and the number of rotations of head is preferably 10 rpm or more and 100 rpm or less. The method for supplying a composition for surface treatment to a polishing pad is also not particularly limited, and for example, a method for continuously supplying (continuous pouring and flowing) with a pump or the like is employed. The supply amount is not limited, and it is preferred that a surface of an object to be subjected to surface treatment is always covered with the composition for surface treatment according to one embodiment of the present invention, and the supply amount is preferably 10 mL/min or more and 5000 mL/min or less. The surface treatment time is not also particularly limited, and is preferably 5 seconds or more and 180 seconds or less in a step of using the composition for surface treatment according to one embodiment of the present invention. Within such a range, the impurities can be removed more favorably.

As the temperature of a composition for surface treatment at the time of surface treatment, it is not particularly limited, and in general, the temperature may be room temperature, or may be raised to around 40° C. or more and 70° C. or less within the range not impairing the performance.

A water-washing step with water may be performed before or after or before and after the surface treatment by the method for surface treatment according to one embodiment of the present invention.

In addition, it is preferred that an object to be subjected to surface treatment in a water-washing step is dried by shaking off the water droplets adhered to the surface with a spin dryer or the like.

<Method for Producing Semiconductor Substrate>

Another one embodiment of the present invention is a method for producing a semiconductor substrate, including a step of treating a surface of a polished object to be polished by the above-described method for surface treatment.

The semiconductor substrate to which the production method of the present invention is applied is preferably a polished semiconductor substrate, and more preferably a semiconductor substrate after CMP. The reason for this is that since in particular, impurities can cause breakdown of a semiconductor device, a step of removing the impurities as much as possible is required as the surface treatment step of a semiconductor substrate, in a case where the polished object to be polished is a polished semiconductor substrate. More specifically, as the semiconductor substrate, for example, a polished semiconductor substrate or the like including a layer containing tungsten, and silicon nitride or TEOS can be mentioned. Specific example of the polished semiconductor substrate include a polished semiconductor substrate or the like having a structure in which tungsten is formed on a silicon nitride film or a TEOS film, and a polished semiconductor substrate having a structure in which a tungsten part, a silicon nitride film, and a TEOS film are all exposed.

As the production method according to one embodiment of the present invention, it is not particularly limited as long as it includes a surface treatment step of reducing the defects on a surface of a polished semiconductor substrate, and for example, a method including a polishing step and a surface treatment step, for forming a polished semiconductor substrate can be mentioned.

[Polishing Step]

The polishing step that can be included in the method for producing a semiconductor substrate according to one embodiment of the present invention is a step of polishing a semiconductor substrate containing silicon nitride or TEOS to form a polished semiconductor substrate.

The polishing step is not particularly limited as long as it is a step of polishing a semiconductor substrate, and the polishing step is preferably a chemical mechanical polishing (CMP) step. In addition, the polishing step may be a polishing step including a single step or a polishing step including multiple steps. As the polishing step including multiple steps, for example, a step of performing a finish polishing step after a preliminary polishing step (rough polishing step); a step of performing a secondary polishing step once or twice after a primary polishing step, and then performing a finish polishing step; or the like can be mentioned.

As the polishing composition, a known polishing composition can be appropriately used depending on the characteristics of the semiconductor substrate. As the polishing composition, it is not particularly limited, and for example, a polishing composition containing abrasive grains, an acid salt, a dispersing medium, and an acid, or the like can be preferably used. As a specific example of the polishing composition, a polishing composition containing sulfonic acid-modified colloidal silica, ammonium sulfate, water, and maleic acid; or the like can be mentioned.

As the polishing device, a common polishing device to which a holder for holding an object to be polished, a motor capable of changing the rotation speed, and the like are attached, and which has a polishing table on which a polishing pad (polishing cloth) can be stuck, may be used. As the polishing device, either a one-side polishing device or a double-side polishing device may be used. Specifically, as the polishing device, for example, Mirra Mesa manufactured by Applied Materials, Inc., FREX 300E manufactured by Ebara Corporation, or the like can be preferably used.

As the polishing pad, a common nonwoven fabric, polyurethane, a porous fluorine resin, or the like may be used without any particular limitation. It is preferred that groove processing is applied to a polishing pad so that a polishing liquid is kept on the polishing pad. It is preferred that groove processing is applied to a polishing pad so that a polishing composition is kept on the polishing pad. Specifically, as the polishing pad, for example, a rigid polyurethane pad IC1000 manufactured by Nitta Haas Incorporated, H800 manufactured by FUJIBO HOLDINGS, INC., or the like can be preferably used.

The polishing conditions are not particularly limited, and for example, the rotation speed of a polishing table and the rotation speed of a head (carrier) are preferably 10 rpm or more and 100 rpm or less, and the pressure (polishing pressure) applied to an object to be polished is preferably 0.5 psi or more and 10 psi or less. The method for supplying a polishing composition to a polishing pad is also not particularly limited, and for example, a method for continuously supplying (continuous pouring and flowing) with a pump or the like can be employed. The supply amount is not limited, but it is preferred that a surface of a polishing pad is always covered with a composition for surface treatment, and the supply amount is preferably 10 mL/min or more and 5000 mL/min or less. The polishing time is not also particularly limited, and is preferably 5 seconds or more and 180 seconds or less in a step of using a polishing composition.

### EXAMPLES

The present invention will be described in more detail by way of the following Examples and Comparative Examples. However, the technical scope of the present invention is not limited only to the following Examples. Note that the expressions “%” and “part(s)” mean “% by mass” and “part (s) by mass”, respectively unless otherwise noted. Further, in the present specification, operations and measurements of properties and the like are performed under the conditions of room temperature (20 to 25 (° C.)/relative humidity 40 to 50% RH, unless otherwise noted.

<Preparation of Composition for Surface Treatment>

[Preparation of Composition for Surface Treatment 1]

A composition for surface treatment 1 was prepared by mixing 0.1% by mass of polystyrene sulfonic acid (manufactured by Alfa Aesar, Mw=75,000) as a polymer compound having a sulfonic acid (salt) group with respect to the final composition for surface treatment, 0.05% by mass of histidine (manufactured by Alfa Aesar) as an inhibitor with respect to the final composition for surface treatment, and a nitric acid aqueous solution (70%) and water (deionized water) so as to obtain a pH of the composition for surface treatment of 3. The pH value of the composition for surface treatment 1 (liquid temperature: 25° C.) was confirmed by a pH meter (model number: LAQUA manufactured by HORIBA Ltd.).

[Preparation of Compositions for Surface Treatment 2 to 18]

Each of the compositions for surface treatment was prepared in a similar manner as in the preparation of a composition for surface treatment 1 except that a polymer compound having a sulfonic acid (salt) group, and an inhibitor were changed to the components with the kinds shown in the following Table 1, respectively. Note that the expression “-” in Table means that the corresponding component was not used.

Product name of each of the components in Table other than the components used for the composition for surface treatment 1 were shown below.
Used for composition for surface treatment 2: arginine (manufactured by Alfa Aesar)
Used for composition for surface treatment 3: lysine (manufactured by Alfa Aesar)
Used for composition for surface treatment 4: cysteine (manufactured by Alfa Aesar)
Used for composition for surface treatment 5: maltitol (manufactured by Alfa Aesar)
Used for composition for surface treatment 6: glycerin (manufactured by J.T. Baker)
Used for composition for surface treatment 7: polyglycerin (model number PGL 40 manufactured by Daicel Corporation, with a weight average molecular weight of 2,981)
Used for composition for surface treatment 8: iminodiacetic acid (manufactured by Sigma-Aldrich Co. LLC)
Used for composition for surface treatment 9: ascorbic acid (manufactured by Sigma-Aldrich Co. LLC)
Used for composition for surface treatment 10: nicotinic acid (manufactured by Sigma-Aldrich Co. LLC)
Used for composition for surface treatment 11: phthalic acid (manufactured by Fluka)
Used for composition for surface treatment 12: pyrazole (manufactured by Sigma-Aldrich Co. LLC)
Used for composition for surface treatment 13: phenyltetrazole (manufactured by TOKYO CHEMICAL INDUSTRY CO., LTD.)
Used for composition for surface treatment 14: benzyl trimethylammonium hydroxide (manufactured by Sigma-Aldrich Co. LLC)
Used for composition for surface treatment 15: nicotinamide (manufactured by Sigma-Aldrich Co. LLC)
Used for composition for surface treatment 16: histidine (manufactured by Alfa Aesar)
Used for composition for surface treatment 17: polyglycerin (model number PGL 40 manufactured by Daicel Corporation, with a weight average molecular weight of 2, 981)

<Preparation of Polished Object to be Polished>

A polished silicon nitride substrate and a polished TEOS substrate, which had been polished in the following chemical mechanical polishing (CMP) step, were prepared as a polished object to be polished.

[CMP Step]

For each of the silicon nitride substrate and the TEOS substrate which were each a semiconductor substrate, by using a polishing composition B (composition: 4% by mass of colloidal silica (manufactured by FUSOU CHEMICAL Co., Ltd., with a primary particle size of 35 nm, and a secondary particle size of 70 nm), adjusted the pH to 5 with maleic acid having a concentration of 30% by mass, and solvent: water), polishing was performed under each of the following conditions. In this regard, for each of the silicon nitride substrate, the TEOS substrate, and a polysilicon substrate, a 300 mm wafer was used.

(Polishing Device and Polishing Condition)

Polishing device: FREX 300E manufactured by Ebara Corporation

Polishing pad: H800 manufactured by FUJIBO HOLDINGS, INC.

Polishing pressure: 2.0 psi (1 psi=6894.76 Pa, the same applies hereinafter)

Rotation speed of polishing table: 90 rpm

Rotation speed of head: 91 rpm

Supply of polishing composition: continuous pouring and flowing

Supply amount of polishing composition: 300 mL/min

Polishing time: 60 seconds

<Surface Treatment Step>

By using each of the compositions for surface treatment prepared in the above or water (deionized water), each of the polished substrates was subjected to surface treatment under the following conditions.

### (Surface Treatment Device and Surface Treatment Condition)

Device: FREX 300E manufactured by Ebara Corporation

Polishing pad: H800 manufactured by FUJIBO HOLDINGS, INC.

Polishing pressure: 1.0 psi

Rotation speed of polishing table: 60 rpm

Rotation speed of head: 63 rpm

Supply of composition for surface treatment: continuous pouring and flowing

Supply amount of composition for surface treatment: 300 mL/min

Surface treatment time: for 60 seconds

<Water-Washing Step>

In the end, to each of the substrates that had been subjected to surface treatment, pure water (DIW) flowed for 1 minute by using a PVA brush, and then spin drying was performed.

<Evaluation>

For each of the polished substrates that had been subjected to surface treatment, the following items were measured and evaluated. The evaluation results are also shown in Table 1.

[Evaluation of Residual Impurities]

By using each of the compositions for surface treatment, a polished substrate was subjected to surface treatment under the surface treatment conditions shown in the above, and then the number of the impurities exceeding 0.12 μm was evaluated. In the evaluation of the number of impurities, SP-1 manufactured by KLA-Tencor Corporation was used to measure the LPD value. The higher the LPD value is, the poorer the impurity residual performance is.

[Evaluation of Rate of Dissolution of Tungsten]

A tungsten substrate (with a thickness of 1000 Å) was cut into 3×3 cm in size, and the cut tungsten substrate was immersed into a composition for surface treatment at 43° C. for 5 minutes. The rate of dissolution of tungsten was determined by using the following equation 1. Further, the results were summarized in Table 1.

[Mathematical formula 1]

Rate of dissolution (Å/min)=[film thickness (Å) of the tungsten substrate before treatment]−[film thickness (Å) of the tungsten substrate after treatment] Equation 1

### [Treatment Time (Min)]

TABLE 1

| | | | | Polymer | | | | | | | | |
|---|---|---|---|---|---|---|---|---|---|---|---|---|
| | | | | compound | | | | | | | | |
| | | | | having sulfonic | | | | | | | | |
| | | | | acid (salt) | | | | | | | | |
| | | | | group | | | Inhibitor or others | | | Number | Number | |
| | | | | | | Concen- | | | Concen- | of | of | Rate of |
| | Composition | | pH | | | tration | | | tration | impurities | impurities | dissolution |
| | for surface | | Adjusting | | | (% by | | | (% by | @ SiN | @ TEOS | of W |
| | treatment | pH | agent | Name | M.W | mass) | Kind | Name | mass) | (>0.12 um) | (>0.12 um) | (Å/min) |
| Example 1 | Composition 1 | 3.0 | Nitric | Poly- | 75,000 | 0.1 | Amino | Histidine | 0.05 | 171 | 71 | 0.2 |
| Example 2 | Composition 2 | | acid | styrene | | | acid | Arginine | 0.05 | 181 | 80 | 0.16 |
| Example 3 | Composition 3 | | | sulfonic | | | | Lysine | 0.05 | 175 | 75 | 0.18 |
| Example 4 | Composition 4 | | | acid | | | | Cysteine | 0.05 | 203 | 81 | 0.3 |
| Example 5 | Composition 5 | | | | | | Polyol | Maltitol | 0.05 | 204 | 78 | 0.23 |
| Example 6 | Composition 6 | | | | | | | Glycerin | 0.05 | 194 | 76 | 0.26 |
| Example 7 | Composition 7 | | | | | | | Poly- | 0.05 | 189 | 69 | 0.24 |
| | | | | | | | | glycerin | | | | |
| Comparative | Composition 8 | | | | | | Organic | Imino- | 0.05 | 194 | 82 | 1.4 |
| Example 1 | | | | | | | acid | diacetic | | | | |
| | | | | | | | | acid | | | | |
| Comparative | Composition 9 | | | | | | | Ascorbic | 0.05 | 188 | 92 | 1.2 |
| Example 2 | | | | | | | | acid | | | | |
| Comparative | Composition | | | | | | | Nicotinic | 0.05 | 210 | 84 | 0.4 |
| Example 3 | 10 | | | | | | | acid | | | | |
| Comparative | Composition | | | | | | | Phthalic | 0.05 | 192 | 78 | 0.44 |
| Example 4 | 11 | | | | | | | acid | | | | |
| Comparative | Composition | | | | | | N- | Pyrazole | 0.05 | 221 | 79 | 1.17 |
| Example 5 | 12 | | | | | | containing | | | | | |
| Comparative | Composition | | | | | | molecule | Phenyl- | 0.03 | 232 | 95 | 1.63 |
| Example 6 | 13 | | | | | | | tetrazole | | | | |
| Comparative | Composition | | | | | | | Benzyl | 0.05 | 219 | 93 | 1.47 |
| Example 7 | 14 | | | | | | | trimethyl- | | | | |
| | | | | | | | | ammon- | | | | |
| | | | | | | | | ium | | | | |
| | | | | | | | | hydro- | | | | |
| | | | | | | | | xide | | | | |
| Comparative | Composition | | | | | | | Nico- | 0.05 | 196 | 87 | 0.47 |
| Example 8 | 15 | | | | | | | tinamide | | | | |
| Comparative | Composition | | | | | | — | — | — | 163 | 70 | 0.7 |
| Example 9 | 16 | | | | | | | | | | | |

| | | | | | | | | |
|---|---|---|---|---|---|---|---|---|
| Comparative | Composition | — | Amino | Histidine | 0.05 | 28658 | 113 | — |
| Example 10 | 17 | | acid | | | | | |
| Comparative | Composition | — | Polyol | Poly- | 0.05 | 55432 | 150 | — |
| Example 11 | 18 | | | glycerin | | | | |

From the results in Table 1, a large amount of impurities remained in Comparative Examples 10 and 11. This is considered to be because the compositions for surface treatment of Comparative Examples 10 and 11 did not have a polymer compound having a sulfonic acid (salt) group, and therefore, the effect of removing impurities was poor. Further, in Comparative Example 9, it is assumed that by using a composition 16 not having an inhibitor, the impurity evaluation on each of SiN and TEOS was good, but the surface roughness of the substrate treated with the composition 16 was deteriorated because the rate of dissolution of tungsten was high. Moreover, from the results of Comparative Examples 1 to 8, it was found that a composition having an inhibitor component other than the components of the present invention was not able to efficiently suppress the rate of dissolution of tungsten. The iminodiacetic acid used in Comparative Example 1 has a structure similar to that of the amino acid according to the present invention, but is easy to form a complex with a metal and dissolves in water, and therefore, the rate of dissolution of tungsten was promoted. On the other hand, in a case of using the amino acid according to the present invention, it is presumed that there was no complex formation as described above.

As can be seen from the results of Examples 1 to 7, the composition of the present invention, containing a polymer compound having a sulfonic acid (salt) group, at least one compound selected from an amino acid and a polyol, and a dispersing medium, was good in impurity evaluation, and was able to greatly suppress the rate of dissolution of tungsten. Accordingly, it is presumed that the surface roughness of a polished object to be polished can be improved.

In addition, in Examples, by using each of a silicon nitride substrate, a TEOS substrate, and a tungsten substrate, the evaluation was made, and also in a case of using a substrate having a structure in which tungsten is formed on a silicon nitride film or a TEOS film, a substrate having a structure in which a tungsten part, a silicon nitride film, and a TEOS film are all exposed, or the like, it can be assumed that evaluation results similar to those described above are obtained.

1. A composition for surface treatment, comprising
a polymer compound having a sulfonic acid (salt) group;
at least one compound selected from an amino acid and a polyol; and
a dispersing medium,
which is used for treating a surface of a polished object to be polished having a layer containing at least tungsten, and tetraethyl orthosilicate or silicon nitride.

2. The composition for surface treatment according to claim 1, wherein
a pH of the composition for surface treatment is acidic.

3. The composition for surface treatment according to claim 1, wherein
the polymer compound having a sulfonic acid (salt) group has a weight average molecular weight of 1,000 or more.

4. The composition for surface treatment according to claim 1, wherein
a PI value of the amino acid is 7.0 or more.

5. The composition for surface treatment according to claim 1, wherein
the amino acid is a basic amino acid.

6. The composition for surface treatment according to claim 1, wherein
the amino acid contains a sulfur atom.

7. The composition for surface treatment according to claim 1, wherein
the polyol is at least one kind selected from a polyhydric alcohol and a saccharide.

8. A method for surface treatment, comprising
treating a surface of a polished object to be polished by using the composition for surface treatment according to claim 1.

9. A method for producing a semiconductor substrate, comprising
treating a surface of a polished object to be polished by the method for surface treatment according to claim 8.
